(19) United States
(12) Patent Application Publication
(10) Pub. No.: US 2026/0136510 A1
(43) Pub. Date: May 14, 2026

(54) METHOD FOR MANUFACTURING A GASKET FOR ELECTROMAGNETIC SHIELDING

(71) Applicant: NOLATO SILIKONTEKNIK AB, Hallsberg (SE)

(72) Inventors: Magnus MATTSSON, Örebro (SE); David NILSSON, Vretstorp (SE)

(73) Assignee: NOLATO SILIKONTEKNIK AB, Hallsberg (SE)

(21) Appl. No.: 19/119,250

(22) PCT Filed: Oct. 18, 2023
(86) PCT No.: PCT/SE2023/051028

§ 371 Date: Apr. 8, 2025

(30) Foreign Application Priority Data
Oct. 18, 2022 (SE) 2251218-0

(51) Int. Cl. H05K 9/00; B05D 3/00

(52) U.S. Cl. CPC H05K 9/0015; B05D 3/207; H05K 9/0083

(57) ABSTRACT

The present disclosure relates to a method for manufacturing a gasket for electromagnetic shielding, wherein the method comprises the steps of:
a) providing a composition comprising i) a viscous material and ii) particles having electrical conductivity and ferromagnetic and/or ferrimagnetic properties;
b) applying said composition to a substrate, by applying the composition in the form of a gasket having a length, a width and a height,
c) applying a magnetic field across said gasket, resulting in a change in a geometry of the gasket, preferably the change results in the height of the gasket increasing,
   wherein the magnetic field applied is in the range of 750-2500 Gauss. The present disclosure further relates to gaskets manufactured by said method and their usage.

### TECHNICAL FIELD

The present disclosure relates generally to a method for manufacturing a gasket for electromagnetic shielding. Further, the present disclosure relates to gaskets for electromagnetic shielding produced by such a method, and their usage.

### BACKGROUND ART

With an increased demand for electronic devices such as computers, mobile phones and other wireless devices, there is a growing need for efficient and optimized components building up said electronic devices.

A common problem when developing electronic devices is electromagnetic interference, EMI, present in the ambience. EMI can disrupt or destroy for instance electrical systems and equipment present in electronic devices, thus damaging them. Furthermore, many electronic devices comprise components which themselves generate EMI that must be shielded so to protect other sensitive components present in the electronic device. As such, it is important to efficiently shield sensitive components from EMI in order to ensure a well-functioning electronic device.

A common solution is to enclose the EMI-emitting or EMI-sensitive component in an electrically conductive casing, thus creating a Faraday cage around said component. If said electrically conductive casing is made up of two or more mating surfaces, the gap or junction between the mating surfaces must be efficiently sealed by an EMI shielding gasket. However, the sealing gasket must at the same time be electrically conductive in order to ensure a functioning Faraday cage.

A proposed solution has been to join two surfaces by a gasket comprising a viscous material and an electrically conductive material dispersed within the viscous material. Traditionally, gaskets were manufactured by dispensing the viscous material comprising the electrically conductive material on a first substrate, following by a treatment so that the viscous material assumes a non-viscous state, and thus a fixed shape. The gasket acts as an electrically conductive sealing joint between the first substrate and a second substrate.

As the electrically conductive material utilized in such gaskets is expensive, different alternatives have been developed to reduce the amount of conductive material needed. One proposed solution to such problem is presented in WO 03037057, disclosing the use of particles that have both electrical and conductive properties.

However, in recent years the industry has strived to manufacture smaller and smaller electronic devices. This poses higher mechanical requirements on the gaskets utilized.

In order to ensure a good sealing effect, the gasket must be compressed between the surfaces of a first and a second substrate to effectively joint the two surfaces. If properly joined, the gasket will ensure that electrical conductivity is achieved between the first and second substrate, and EMI shielding is achieved between the inside and the outside of the gasket, i.e. electromagnetic interference does not pass through the gasket.

If the compression force required to effectively join two surfaces by a gasket and achieving electrical conductivity is too high, the substrates used can be damaged. This is especially a problem in the development of small electronic devices as smaller, hence more fragile, components are needed to manufacture these devices. A high compression force requires for instance the use of a thicker cover and a shorter distance between screws, thus leading to an increase in product related costs for the manufacture of electronic devices.

While the solution proposed in WO 03037057 reduces the amount of expensive particles needed compared to the previously known solutions in the art, it is silent about specific crucial product parameters such as the electromagnetic shielding achieved, electrical conductivity of the gasket material and compression force of the gasket.

There is thus still a need to provide a gasket for electromagnetic shielding exhibiting sufficiently good EMI shielding and electrical conductivity, while at the same time exhibiting low compression force and compression set compared to previously known solutions.

### SUMMARY OF DISCLOSURE

An object of the present disclosure is to provide an improved method of manufacturing a gasket for electromagnetic shielding.

Another object is to provide a method of manufacturing a gasket for electromagnetic shielding, resulting in a gasket that exhibits good electromagnetic shielding properties, good electrical conductivity properties and low compression force and compression set compared to the prior art.

Another object of the present disclosure is to provide a gasket for electromagnetic shielding.

Another object is to provide a gasket for electromagnetic shielding exhibiting good electromagnetic shielding properties, electrical resistance properties and low compression force compared to the prior art.

Another object of the present disclosure is to provide a gasket for electromagnetic shielding to be used for electromagnetic shielding in a product such as an electronic device.

In a first aspect, the present disclosure is directed to a method for manufacturing a gasket for electromagnetic shielding, wherein the method comprises the steps of:
a. providing a composition comprising i) a viscous material and ii) particles having electrical conductivity and ferromagnetic and/or ferrimagnetic properties;
b. applying said composition to a substrate, by applying the composition in the form of a gasket having a length, a width and a height,
c. applying a magnetic field across said gasket, resulting in a change in a geometry of the gasket, preferably the change results in the height of the gasket increasing, and
   wherein the magnetic field applied is in the range of 750-2500 Gauss.

The composition may be applied to a substrate by any one of a dispersion process, a jet dispensing process or a screen printing process.

By applying a magnetic field in the range of 750-2500 Gauss to the composition, a gasket for electromagnetic shielding is manufactured having both sufficiently good EMI shielding properties and electrical resistance, as well as compression force and compression set. The magnetic field may be applied in a direction so as to act perpendicular to the gasket along a longitudinal extension.

By compression force is meant the force required to compress the gasket by 50%. The value is indicative of the force required to compress the gasket in order to effectively join two substrates, and thus ensuring that EMI shielding is achieved between the inside and the outside of the gasket, and that electrical conductivity is achieved between the two substrates joined. By compression set, is meant the permanent deformation of the gasket remaining after removal of a force that was applied to the gasket.

It is important that the magnetic field applied is sufficiently strong so that the particles present in the composition can interact with the magnetic field. Due to the ferromagnetic and/or ferrimagnetic properties of the particles, the particles will be affected by the magnetic field and orient themselves in the same direction as the magnetic field. If sufficiently strong, the interaction of the particles with the magnetic field will lead to the gasket changing in geometry when the particles move with the magnetic field applied. Preferably, the change in geometry results in a height increase of the gasket, meaning that the gasket will change its shape from a D-shape to a triangular geometry with a shape tapering from a base towards an apex. A tapering shape is desired as this reduces the compression force of the gasket. In one embodiment of the present disclosure, the applied magnetic field results in an increase in height and a reduction in width of the gasket.

In order to create the desired tapering shape, it is thus important that the magnetic field applied is sufficiently strong so to be able to change the geometry of the gasket. However, it has been discovered that a too strong magnetic field will negatively affect some properties of the formed gasket. For instance, the inventors have discovered that a too strong magnetic field will result in impaired electrical resistance properties, meaning a reduced ability to conduct electricity. Good electrical conductivity is a crucial parameter for gaskets used in electronic devices.

Moreover, a too strong magnetic field will also lead to reduced shielding properties. If the magnetic field applied changes the geometry of the gasket excessively, the shielding properties will be impaired by either the gasket becoming too thin so that it can be penetrated by the electromagnetic waves, or becoming so thin it will tilt during assembly when two substrates are joined by the gasket, thus leaving a gap open.

A gasket manufactured according to a method of the present disclosure may be utilised for shielding electronic devices and equipment, such as for instance a base station for mobile telephone. In such a case, the gasket is arranged on a substrate after which the substrate is subsequently closed with a suitably designed mating substrate. The substrate may be a casing. The gasket will ensure that good electrical contact is provided between the two substrates, and also provide electromagnetic shielding between the inside and outside of the gasket.

In one exemplary method, the applied magnetic field is in the range of 750-2250 Gauss.

In one exemplary method, the applied magnetic field is in the range of 1000-2000 Gauss.

By such exemplary method, a gasket for electromagnetic shielding is manufactured, wherein said gasket having optimized EMI shielding properties and electrical resistance, as well as compression force and compression set. As previously described, and as demonstrated in the present disclosure, it has been discovered that the strength of the magnetic field applied highly affects these four properties, and that an optimum for these properties is achieved when using a magnetic field strength according to the present disclosure.

As disclosed above, the gasket comprises particles having electrical conductivity and ferromagnetic and/or ferrimagnetic properties. In one exemplary method, the particles comprise an inner layer comprising nickel, graphite, iron, cobalt, or an alloy containing two or more of these. The particles may further comprise an outer layer comprising silver or nickel. In one embodiment, the particles comprise a first layer comprising nickel with an outer layer comprising silver. In one embodiment, the particles comprise an inner layer comprising graphite and an outer layer comprising nickel. In one embodiment, the particles comprise an inner layer comprising graphite, an intermediate layer comprising nickel, and an outer layer comprising silver.

By such exemplary method, it is possible to provide particles having improved magnetic properties and electrical conductivity properties, meaning that the amount of particles required to achieve sufficiently good electrical conductivity is decreased, and hence that costs are reduced.

In one exemplary method, the particles have a diameter in the range of 15-180 μm, preferably between 30-90 μm, preferably between 40-80 μm, preferably having an average diameter of around 60 μm. The particles need to be sufficiently large to be able to create electrical contact between each other so to conduct electricity. However if too large, the particles will result in production difficulties with needle blocking and production stops during dispensing with a thin dispensing needle needed to create the required gasket height and width.

In one exemplary method, the method further comprises a curing step d), wherein the curing step results in a cured gasket being in an elastic, non-viscous state. Preferably, the curing is performed by a temperature treatment at 10-250 degrees C., preferably by a temperature treatment at 60-200 degrees C. for a period of at least 15 min or by a temperature treatment at 15-60 degrees C. for a period of at least 6 hours. By curing the gasket, it is ensured that a gasket with a fixed shape is formed.

In one exemplary method, the gasket after the curing step d) comprises 10-50 weight-% of viscous material and 50-90 weight-% of particles. As previously described, the gasket needs to comprise a sufficiently high amount of particles in order to conduct electricity, while at the same time having a viscosity suitable for applying the composition forming the gasket in an industrially feasible manner.

In one exemplary method, the gasket after the curing step d) comprises 20-40 weight-% of viscous material and 60-80 weight-% of particles.

In one exemplary method, the composition further comprises a viscous reducing agent, preferably selected from Toluene, Xylene, a petroleum distillate with a boiling point between 50 and 250 degrees C. or a silicone oil with a boiling point between 50 and 250 degrees C. By including a viscous reducing agent, a composition that is easier to dispense is achieved. Preferably, the viscous reducing agent evaporates during the curing step d).

In one exemplary method, the composition comprises 5-50 weight-% of viscous material and 50-90 weight-% of particles and 2-20 weight-% of a viscous reducing agent. Increasing the amount of particles, and hence the electrical conductivity, may result in an increase in viscosity of the composition. This may be undesirable as a composition having a too high viscosity may be difficult to apply on a substrate.

In one exemplary method, the composition comprises 15-40 weight-% of viscous material and 60-80 weight-% of particles and 5-15 weight-% of a viscous reducing agent.

In one exemplary method, the magnetic field is applied during 5-15 seconds. This time interval ensures that the gasket is subjected to the magnetic field for a sufficiently long time in order to change the geometry of the gasket and thus provide excellent EMI shieling properties and electrical conductivity properties to said gasket.

In one exemplary method, the viscous material is selected from silicone rubber, polyurethane and thermoplastic elastomer.

In one exemplary method, the composition has a viscosity of 20-120 Pas. In order to ensure a good dispensability, it is important that the composition has a low viscosity. At the same time, the viscosity must be sufficiently high so that the composition, after being applied to a substrate, retains its shape (height and width) and does not flow out before it has had time to harden or cure. The inventors have found that an optimal viscosity providing for both of the above mentioned requirements is between 20 and 120 Pas. In one exemplary method, the viscosity of the composition is between 40 and 100 Pas.

The viscosity is measured using a Haake Rotovisco rheometer equipped with a plate-to-plate system at a shear rate of 10 s⁻¹. The distance between the two plates is 0.5 mm. The measurement is made at 23 degrees C. and the result is given in Pas.

In a second aspect, the present disclosure is directed to a gasket for electromagnetic shielding produced by any method according to the first aspect.

In one exemplary gasket, the gasket has a resistance lower than 1Ω, preferably lower than 0.5Ω, when measuring the resistance according to the method disclosed in the present disclosure. The electrical resistance is measured by pressing, with a force of 7.5 N onto the gasket, two square electrodes each with a dimension of 10×10 mm. The distance between the two electrodes is set to 10 mm on to the gasket.

In a third aspect, the present disclosure is directed to a gasket according to the second aspect, to be used for electromagnetic shielding in an electronic device, such as a mobile communication device, a base station, a computer device or electronic enclosures in automotive applications.

### BRIEF DESCRIPTION OF DRAWINGS

The disclosure is now described, by way of example, with reference to the accompanying drawings, in which:

FIG. 1 illustrates a gasket applied to a substrate before a magnetic field is applied to the gasket according to the present disclosure.

FIG. 2, showing an embodiment of the present disclosure, illustrates a gasket that has been subjected to a magnetic field according to the present disclosure.

FIG. 3 illustrated two substrates joined by a gasket according to the present disclosure.

### DESCRIPTION OF EMBODIMENTS

The detailed description with reference to the disclosed embodiments are to be viewed as examples of combining specific features described above. It is to be understood that additional examples may be achieved by combining other and/or fewer/more features than in the disclosed embodiments. Hence, the figures disclose exemplary embodiments and not exclusive combinations. In this context is should also be noted that, for the sake of simplicity, all figures are schematically disclosed, as long as nothing else is said.

As used herein, “weight-%” refers to weight percent of the ingredient referred to of the total weight of the compound or composition referred to.

The present disclosure relates to a method for manufacturing a gasket for electromagnetic shielding comprising a step of, among others, applying a magnetic field in the range of 750-2500 Gauss across a gasket. The applied magnetic field according to the present disclosure results in a gasket for electromagnetic shielding exhibiting both good electromagnetic shielding properties, electrical conductivity properties and compression force.

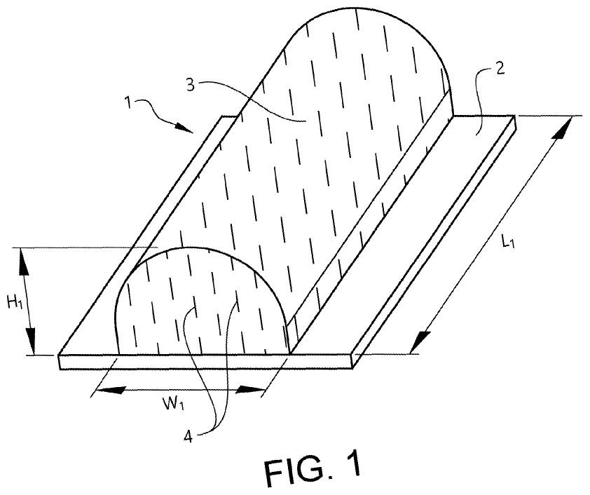

FIG. 1 illustrates a part-sectional view of a gasket 1 in a state before a magnetic field according to the present disclosure has been applied. As previously described, the gasket is manufactured by applying a composition to a substrate 2. In the embodiment illustrated in FIG. 1, the gasket is applied so that a length L1, a width W1 and a heigh H1 is formed. The composition, forming the gasket 1, comprises a viscous material 3 and particles 4 having electrical conductivity and ferromagnetic and/or ferrimagnetic properties.

The composition may be applied by dispensing the composition from a needle nozzle (not illustrated) which is moved over the substrate 2 along a predefined extension of the substrate.

The viscous material 3 may be selected from silicone rubber, polyurethane and thermoplastic elastomer.

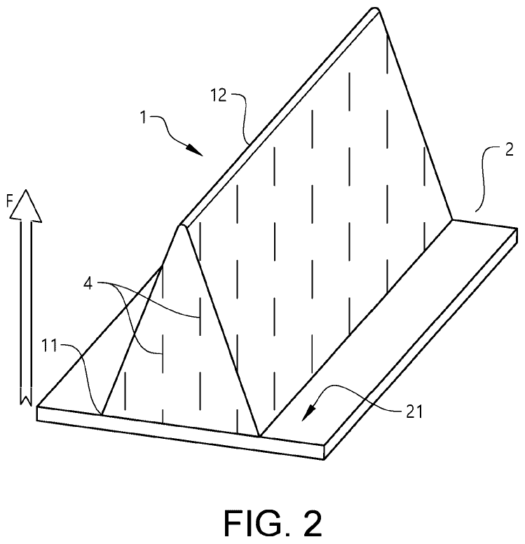

Turning now to FIG. 2, illustrating a gasket 1 that has been subjected to a magnetic field F according to the present disclosure. For the sake of clarity, the applied magnetic field is illustrated by arrow F.

The magnetic field F is applied across the gasket 1 in a direction so as to act perpendicular to the gasket 1 and substrate 2. In the embodiment illustrated in FIG. 2, the magnetic field F is applied in a direction away from an upper surface 21 of the substrate 2 on which the gasket 1 is arranged. The magnetic field F may be applied by a magnetic device (not illustrated) such as an electromagnet.

When the gasket 1, comprising particles 4 having electrical conductivity and ferromagnetic and/or ferrimagnetic properties is subjected to a magnetic field F, the particles 4 will be affected by the magnetic field F and orient themselves in the same direction as the magnetic field F. Due to the force of the magnetic field, the overall geometry of the gasket 1 will also change to a more tapering shape. After the magnetic field has been applied, the gasket 1 may exhibit a different, i.e. increased, height. In the embodiment illustrated in FIG. 2, the gasket 1 has assumed an essentially triangular geometry with a shape tapering from a base 11 to an apex 12.

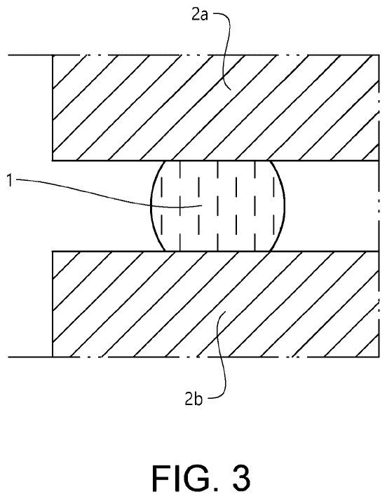

Turning now to FIG. 3 illustrating two substrates 2a and 2b joined by a gasket 1 according to the present disclosure. The gasket 1 ensures good electrical conductivity between substrate 2a and substrate 2b, thus creating a Faraday Cage.

Further, due to the electromagnetic shielding properties of the gasket 1, it also inhibits electromagnetic waves from traveling between the seal formed.

### EXAMPLES

In the following examples, two different compositions are analysed. The compositions are treated with different magnetic field strength and the resulting electromagnetic shielding properties, electrical resistance, compression force and compression set are evaluated.

### Materials:

Composition A: Fluid silicone rubber comprising a hydrocarbon solvent and particles comprising an inner layer comprising nickel and an outer layer comprising silver.

Composition A comprised 15-40 weight-% of the viscous material, 60-80 weight-% of particles, and 5-15 weight-% of the viscous reducing agent.

Composition B: Fluid silicone rubber comprising a hydrocarbon solvent and particles comprising an inner layer comprising graphite and an outer layer comprising nickel.

Composition B comprised 15-40 weight-% of the viscous material, 60-80 weight-% of particles, and 5-15 weight-% of the viscous reducing agent.

### Example 1: Compression Force Analysis

Firstly, in order to analyse the compression force of gaskets manufactured with different magnetic field strengths, two different gaskets made of either composition A or B are dispensed on an aluminium sheet. Subsequently, each gasket is treated by applying a magnetic field across said gasket by using an electromagnet for a period of 15 seconds. Four different magnetic field strength are investigated. Lastly, the treated gaskets are subjected to a curing at 150 degrees C. for 30 minutes. The gaskets are dispensed with dimensions that, after the application of the magnetic field and the curing step, result in a height of the treated gasket of 1.6 mm.

The gaskets are then analysed for their compression force and how the strength of the applied magnetic field affects the compression force.

Measurements are carried out in a tensile testing machine capable to measure force and deflection. In the present disclosure, a tensile testing machine of the mark Hounsfield H5K-S machine is utilised. Three measurements were made for gaskets manufactured with composition A, and six measurements were made for gaskets manufactured with composition B. The gasket is compressed by a probe with a dimension of 10×10 mm up to 50% of the original thickness of the gasket. The compression speed utilised is 1 mm/min. The results are shown in Table 1.

TABLE 1

| Composition - Magnetic field strength | Compression force at 50% |
|---|---|
| (Gauss) | compression (N) |
| A - 500 Gauss | 81 ± 3 |
| A - 1000 Gauss | 64 ± 1 |
| A - 3800 Gauss | 44 ± 3 |
| B - 500 Gauss | 66 ± 3 |
| B - 2000 Gauss | 33 ± 1 |
| B - 3800 Gauss | 28 ± 1 |

As can be seen, the compression force required to compress 50% of the gasket manufactured from compositions A or B is reduced when the strength of the applied magnetic field is increased. If the gasket is used to join two substrates together, this signifies that less force is required to effectively compress the gasket to join and seal the substrates together. This is a desired property as the gasket needs to provide good electrical contact between the substrates.

### Example 2: Electrical Resistance Analysis

Firstly, in order to analyse the electrical resistance (i.e. the electrical conductivity) of gaskets produced with different magnetic field strengths, two different gaskets made of either composition A or B are dispensed on an aluminium sheet. Subsequently, each gasket is treated by applying a magnetic field across said gasket by using an electromagnet for a period of 15 seconds. Four different magnetic field strength are investigated. Lastly, the treated gaskets are subjected to a curing at 150 degrees C. for 30 minutes. The gaskets are dispensed with dimensions that, after the application of the magnetic field and the curing step, result in a height of the treated gasket of 1.6 mm.

The gaskets are then analysed for their electrical resistance and how the strength of the applied magnetic field affects the electrical resistance of the gasket.

The electrical resistance is measured by pressing, with a force of 7.5 N onto the gasket, two square electrodes each with a dimension of 10×10 mm. The distance between the two electrodes is set to 10 mm on to the gasket. Six measurements were performed for each material and magnetic strength. The results are shown in Table 2.

TABLE 2

| Composition - Magnetic field strength | |
|---|---|
| (Gauss) | Resistance (mΩ) |
| A - 500 Gauss | 200 ± 28 |
| A - 1000 Gauss | 63 ± 24 |
| A - 3800 Gauss | 120 ± 24 |
| B - 500 Gauss | 92 ± 5 |
| B - 2000 Gauss | 85 ± 4 |
| B - 3800 Gauss | 105 ± 4 |

As can be seen, gaskets produced either by compositions A or B show an electrical resistance optimum at 1000 Gauss respectively 2000 Gauss. As previously described, low electrical resistance is a crucial parameter for gaskets used in electronic devices. If a gasket having a high electrical resistance is used in an insulating casing to join two substrates, the casing might not effectively protect components inside the insulating casing from electromagnetic interference, and thus damaging the functioning of the components.

### Example 3: Electromagnetic Shielding Analysis

Firstly, in order to analyse the electromagnetic shielding properties of gaskets produced with different magnetic field strengths, two different gaskets made of either composition A or B are dispensed on a cavity plate made of aluminium. Subsequently, each gasket is treated by applying a magnetic field across said gasket by using an electromagnet for a period of 15 seconds. Four different magnetic field strength are investigated. Lastly, the treated gaskets are subjected to a curing at 150 degrees C. for 30 minutes. The gaskets are dispensed with dimensions that, after the application of the magnetic field and the curing step, result in a height of the treated gasket of 1.6 mm.

The gaskets are then analysed for their electromagnetic shielding properties and how the strength of the applied magnetic field affects the electromagnetic shielding properties of the gasket.

Prior to testing, a cover is attached to the cavity plate with bolts to close the cavities. Spacer are placed in between cavity fixture and cover so that the gasket is compressed 37% compared to its original height. The dimensions of the gasket were determined by an optical measuring machine. One short circuited probe is assembled in each cavity. A network analyser is connected and used to feed a signal into one of the cavities and to measure interference inside the other cavity. The shielding effect of the gasket is measured in dB as the S21 response over the frequency range from 0.3 up to 20 GHz. The results are shown in Table 3.

TABLE 3

| Composition - Magnetic field strength | Electromagnetic shielding (dB) |
|---|---|
| (Gauss) | (0.3-20 GHz) |
| A - 500 Gauss | 52 |
| A - 1000 Gauss | 62 |
| A - 3800 Gauss | 48 |
| B - 500 Gauss | 138 |
| B - 2000 Gauss | 135 |
| B - 3800 Gauss | 94 |

As can be seen, a clear optimum in electromagnetic shielding is achieved for gaskets manufactured with composition A when applying a magnetic field of 1000 Gauss. If the strength of the magnetic field is increased for composition A, an impaired electromagnetic shielding is achieved. For gaskets manufactured with composition B, high values for electromagnetic shielding are achieved when treating gaskets with a magnetic field with a strength of 500 Gauss or 2000 Gauss. However, increasing the magnetic field strength to above 3000 Gauss results in deteriorated shielding properties.

### Example 4: Compression Set

Firstly, in order to analyse the compression set of gaskets produced with different magnetic field strengths, two different gaskets made of either composition A or B are dispensed on an aluminium sheet. Subsequently, each gasket is treated by applying a magnetic field across said gasket by using an electromagnet for a period of 15 seconds. Four different magnetic field strength are investigated. Lastly, the treated gaskets are subjected to a curing at 150 degrees C. for 30 minutes. The gaskets are dispensed with dimensions that, after the application of the magnetic field and the curing step, result in a height of the treated gasket of 1.6 mm.

The gaskets are then analysed for their compression set.

Testing was performed according to ISO 815 with the exception that the test was performed on a dispensed gasket instead of the standardized moulded cylindrical test specimen.

Height was measured post curing by an optical measuring machine. Subsequently, the gaskets were subjected to a compression of 25% and placed into an oven at 100 degrees C. for 72 hours. After testing, the height of the specimens was measured after recovery of 30 minutes. Compression set was calculated using equation 1.

$$\frac{{h}_{0} - {h}_{1}}{{h}_{0} - {h}_{s}} \times 100 \qquad ( equation 1 )$$

wherein h₀ is the initial thickness of the test piece (in millimetres), h₁ is the thickness of the test piece after recovery (in millimetres), hₛ is the height of the space (in millimetres).

The results are shown in Table 4.

TABLE 4

| Composition - Magnetic field strength | |
|---|---|
| (Gauss) | Compression set (%) |
| A - 500 Gauss | 49.6 ± 1.1 |
| A - 1000 Gauss | 32.2 ± 4.3 |
| A - 3800 Gauss | 31.7 ± 4.7 |
| B - 500 Gauss | 24.5 ± 2.4 |
| B - 2000 Gauss | 19.4 ± 3.6 |
| B - 3800 Gauss | 19.6 ± 3.6 |

As can be seen, by utilising a stronger magnetic field strength, gaskets manufactured from composition A or B, that retain their shape after prolonged compression are achieved, meaning a gasket performing better during the lifetime of the gasket.

Examples 1-4 demonstrate that a clear optimum with regards to electrical resistance, electromagnetic shielding, compression force and compression set may be achieved when manufacturing gaskets by applying a magnetic field with a strength according to the present disclosure. As can be seen, treating a gasket with a strong magnetic field results in a softer gasket, i.e. lower compression force, and low compression set values. This may be attributed to the fact that a stronger magnetic field will change the geometry of the gasket more and thus increase the height and decrease the width of the triangular gasket formed.

However, if the magnetic field strength is increased excessively, the electrical resistance of the gasket is impaired, as demonstrated in Example 2. Moreover, as also demonstrated in Example 2, a weak magnetic field results in a high electrical resistance in the gasket and thus reduced electrical conductivity. As the gasket may be utilised in casings to protect sensitive components inside such a casing, it is important that the resistance of the gasket is low so to achieve good electric conductivity.

Similarly, also the electromagnetic shielding properties of gaskets is impaired if the magnetic strength is too strong, as can be seen in Example 3. The applicant has discovered that in order to achieve sufficiently good values of all these parameters (electrical resistance, electromagnetic shielding, compression force and compression set), and thus obtaining a gasket with improved properties compared to the prior art, it is preferred to manufacture the gasket according to the method for manufacturing according to the present disclosure.

1-18. (canceled)

19. A method for manufacturing a gasket for electromagnetic shielding, wherein the method comprises the steps of:
a) providing a composition comprising i) a viscous material and ii) particles having electrical conductivity and ferromagnetic and/or ferrimagnetic properties;
b) applying said composition to a substrate, by applying the composition in the form of a gasket having a length, a width and a height,
c) applying a magnetic field across said gasket, resulting in a change in a geometry of the gasket,
wherein the magnetic field applied is in the range of 750-2500 Gauss.

20. A method according to claim 19, wherein the change in a geometry of the gasket in step c) results in the height of the gasket increasing.

21. A method according to claim 19, wherein the applied magnetic field is in the range of 750-2250 Gauss.

22. A method according to claim 19, wherein the applied magnetic field is in the range of 1000-2000 Gauss.

23. A method according to claim 19, wherein said particles comprise an inner layer comprising nickel, graphite, iron, cobalt, or an alloy containing two or more of these.

24. A method according to claim 23, wherein the particles further comprise an outer layer comprising silver or nickel.

25. A method according to claim 19, wherein said particles have a diameter in the range of 15-180 μm.

26. A method according to claim 19, wherein the method further comprises a curing step d), wherein the curing is performed by a temperature treatment at 10-250 degrees C.

27. A method according to claim 26, wherein the gasket after the curing step d) comprises 10-50 weight-% of viscous material and 50-90 weight-% of particles.

28. A method according to claim 26, wherein the gasket after the curing step d) comprises 20-40 weight-% of viscous material and 60-80 weight-% of particles.

29. A method according to claim 19, wherein the composition further comprises a viscous reducing agent.

30. A method according to claim 29, wherein the composition comprises 5-50 weight-% of viscous material and 50-90 weight-% of particles and 2-20 weight-% of a viscous reducing agent.

31. A method according to claim 29, wherein the composition comprises 15-40 weight-% of viscous material and 60-80 weight-% of particles and 5-15 weight-% of a viscous reducing agent.

32. A method according to claim 19, wherein the magnetic field is applied for 5-15 seconds.

33. A method according to claim 19, wherein the viscous material is selected from silicone rubber, polyurethane and thermoplastic elastomer.

34. A method according to claim 19, wherein the composition has a viscosity of 20-120 Pas.

35. A method according to claim 19, wherein the composition has a viscosity of 40-100 Pas.

36. A gasket for electromagnetic shielding produced by a method according to claim 19.

37. A gasket for electromagnetic shielding according to claim 36, wherein the gasket has a resistance lower than 1Ω, when measuring the resistance according to the method disclosed in the present disclosure.

38. Use of a gasket according to claim 36, for electromagnetic shielding in a product such as a mobile communication device, a base station, a computer device or electronic enclosures in automotive applications.
